(19) United States
(12) Patent Application Publication
(10) Pub. No.: US 2011/0290300 A1
(43) Pub. Date: Dec. 1, 2011

(54) PRODUCTION OF SOLAR CELL MODULES

(75) Inventors: Peter Battenhausen, Brachttal-Udenhain (DE); Ernst Becker, Bensheim (DE); Klaus Schultes, Wiesbaden (DE); Sven Strohkark, Darmstadt (DE)

(73) Assignee: EVONIK ROEHM GMBH, Darmstadt (DE)

(21) Appl. No.: 13/123,544

(22) PCT Filed: Oct. 15, 2009
(86) PCT No.: PCT/EP2009/063438

§ 371 Date: Apr. 11, 2011

(30) Foreign Application Priority Data
Nov. 13, 2008 (DE) 10 2008 043 713.1

(51) Int. Cl. H01L 31/048; H01L 31/052

(52) U.S. Cl. 136/246; 136/251

(57) ABSTRACT

The invention relates to the use of a) at least one polyalkyl(meth)acrylate and b) at least one compound according to formula (I), where the groups R¹ and R² independently represent an alkyl or cycloalkyl group with 1 to 20 carbon atoms, for the production of solar cell modules, particularly for the production of light concentrators for solar cell modules.

The present invention relates to the production of solar-cell modules, and also to the corresponding solar-cell modules.

### PRIOR ART

A solar cell or photovoltaic cell is an electrical module which converts the radiant energy in light, in particular that in sunlight, directly into electrical energy. The physical basis of this conversion is the photovoltaic effect, which is a specific instance of the internal photoelectric effect.

FIG. 3 is a cross-sectional diagram showing the fundamental structure of a solar-cell module. 501 in FIG. 3 indicates a photovoltaic element, 502 indicates a fixing means, 503 indicates a pane, and 504 indicates a rear wall. Radiation from sunlight impacts the light-sensitive surface of the photovoltaic element 501 by passing through the pane 503 and the fixing means 502, and is converted into electrical energy. Output terminals (not shown) serve for output of the resultant electricity.

The photovoltaic element cannot withstand extreme outdoor conditions, because it readily corrodes and is very fragile. It therefore has to be covered and protected by a suitable material. In most instances, this is achieved by using a suitable fixing means to insert and laminate the photovoltaic element between a transparent weathering-resistant pane, e.g. a pane of glass, and a rear wall which has excellent moisture resistance and high electrical resistance.

Materials often used as fixing means for solar cells are polyvinyl butyral and ethylene-vinyl acetate copolymers (EVA). In particular, crosslinkable EVA compositions exhibit excellent properties here, examples being good heat resistance, high weathering resistance, high transparency and good cost-efficiency.

The solar-cell module is intended to have high stability because it is intended for long-term outdoor use. Accordingly, the fixing means must inter alia have excellent weathering resistance and high heat resistance. However, a phenomenon frequently observed when the module is in long-term outdoor use, for example for a period of ten years, is light-induced and/or heat-induced degradation of the fixing means, leading to yellowing of the fixing means and/or peeling from the photovoltaic element. The yellowing of the fixing means leads to a reduction in the utilizable proportion of the incident light, with a consequent reduction in electrical power level. Secondly, peeling from the photovoltaic element allows penetration of moisture, and this can lead to corrosion of the photovoltaic element itself or of metallic parts in the solar-cell module, and likewise reduces the power obtained from the solar-cell module.

Although the EVAs usually used are good fixing means per se, they are gradually degraded by hydrolysis and/or pyrolysis. Over the course of time, acetic acid is liberated by the action of heat or moisture. This leads to yellowing of the fixing means, to a reduction in mechanical strength and to a reduction in the adhesion of the fixing means. Furthermore, the acetic acid liberated acts as catalyst and further accelerates degradation. A further problem arising is that the acetic acid corrodes the photovoltaic element and/or other metal parts in the solar-cell module.

To solve the said problems, European Patent Application EP 1 065 731 A2 proposes the use of a solar-cell module which encompasses a photovoltaic element and a polymeric fixing means, where the polymeric fixing means is intended to comprise an ethylene-acrylate-acrylic acid terpolymer, an ethylene-acrylate-maleic anhydride terpolymer, an ethylene-methacrylate-acrylate terpolymer, an ethylene-acrylate-methacrylic acid terpolymer, an ethylene-methacrylate-methacrylic acid terpolymer and/or an ethylene-methacrylate-maleic anhydride terpolymer. However, solar-cell modules of this type have restricted weathering resistance and also restricted effectiveness.

The prior art also discloses improvement of the weathering resistance of acrylic moulding compositions by use of suitable UV absorbers.

By way of example, DE 103 11 641 A1 describes tanning aids which comprise a polymethyl methacrylate moulding which comprises from 0.005% by weight to 0.1% by weight of a UV stabilizer according to formula (I)

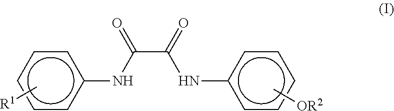

in which the moieties R¹ and R² are independently an alkyl or cycloalkyl moiety having from 1 to 20 carbon atoms.

However, the publication reveals nothing about the use of the mouldings for the production of solar-cell modules.

DE 38 38 480 A1 discloses methyl methacrylate polymers and methyl methacrylate copolymers which respectively comprise
a) an oxanilide compound or 2,2,6,6-tetramethylpiperidine compound as stabilizer for protection from damage caused by light, and
b) a flame-retardant organophosphorus compound.

However, the publication reveals nothing about the use of the composition for the production of solar-cell modules.

JP 2005-298748 A provides mouldings composed of a methacrylic resin, and these preferably comprise 100 parts by weight of methacrylic resin, encompassing from 60 to 100% by weight of methyl methacrylate units and from 0 to 40% by weight of other copolymerizable vinyl monomer units, and from 0.005-0.15% by weight of 2-(2-hydroxy-4-n-octyloxyphenyl)-4,6-bis(2,4-dimethylphenyl)-1,3,5-triazine and/or 2-hydroxy-4-octyloxybenzophenone. The mouldings are intended to have a significant barrier for UV radiation and to have transparency of at most 20% at 340 nm and transparency of at least 70% at 380 nm, measured on mouldings of thickness in the range from 0.5 to 5 mm.

The mouldings are in particular intended to be used as covers for lighting systems. However, the publication reveals nothing about the use of the mouldings for the production of solar-cell modules.

### BRIEF DESCRIPTION OF THE INVENTION

It is therefore an object of the present invention to provide possibilities for mitigating the reduction in power from a solar cell during long-term outdoor use, in particular at high temperature and/or high humidity. To this end, methods were in particular sought for achieving excellent weathering resistance, maximum heat resistance and maximum permeability to light, and also minimum water absorption. Other desirable features are minimum liberation of substances that promote corrosion, in particular of acids, and maximum adhesion to the various substrate elements of a solar-cell module.

Use of a moulding composition with all of the features of the present Patent Claim 1 achieves the said objects, and also achieves other objects which although not specifically mentioned are obvious from the circumstances discussed in the introduction. The dependent claims that refer back to Claim 1 describe particularly advantageous variants of the invention. Protection is also provided for the corresponding solar-cell modules.

Use of

a) at least one polyalkyl (meth)acrylate and
b) at least one compound according to formula (I)

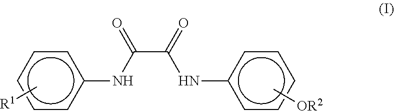

in which the moieties R¹ and R² are independently an alkyl or cycloalkyl moiety having from 1 to 20 carbon atoms,
   for the production of solar-cell modules, in particular for the production of light concentrators for solar-cell modules,
   is a successful, but not readily foreseeable, method of optimizing mitigation of any reduction in the power from a solar cell during long-term outdoor use, in particular at high temperature and/or high humidity. In particular, excellent weathering resistance, very high heat resistance and very high permeability to light, and also very low water absorption are achieved. Furthermore, even long-term outdoor use results in no liberation of substances that promote corrosion, while the adhesion achieved to the various substrate elements of a solar-cell module is very good.

This manner of achieving the object permits efficient utilization of “useful” light in the visible wavelength range. At the same time, other wavelength ranges, in particular in the UV region, which cannot be utilized to generate electricity, are effectively absorbed. The said absorption increases the weathering resistance of the solar-cell modules. The absorption moreover inhibits disadvantageous heating of the light collectors, without a need to use cooling elements for the said purposes, and the lifetime of the solar-cell modules is prolonged, and their total output and their effectiveness is increased.

The procedure according to the invention in particular gives the following advantages:

Access is provided to a solar-cell module with excellent weathering resistance, heat resistance and moisture resistance. No peeling occurs, even when the module is exposed to outdoor conditions for a long period. Weathering resistance is moreover improved, since no acid is liberated even at high temperatures and high humidity. Since there is no corrosion of the photovoltaic element caused by acid, a long-lasting stable power level is maintained by the solar cell over a long period.

Materials are moreover used whose weathering resistance, heat resistance and moisture resistance are excellent, and which have excellent permeability to light, and which permits the production of very good solar-cell modules.

### DESCRIPTION OF THE DRAWINGS

FIG. 1 is a cross-sectional diagram of a preferred solar-cell module according to the present invention.

FIGS. 2a and 2b are cross-sectional diagrams showing the fundamental structure of a photovoltaic element preferably used in the solar-cell module according to FIG. 1, and, respectively, a plan view of the light-sensitive area of the photovoltaic element.

FIG. 3 is a cross-sectional diagram of a conventional solar cell.

### KEY

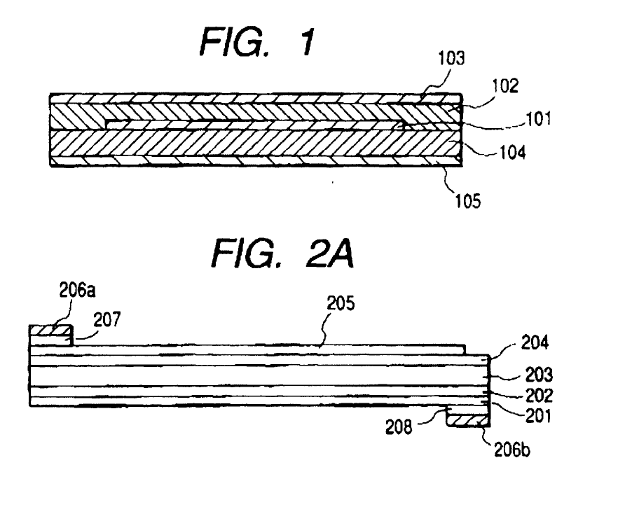

FIG. 1
101 Photovoltaic element
102 Fixing means
103 Pane
104 Fixing means
105 Rear wall

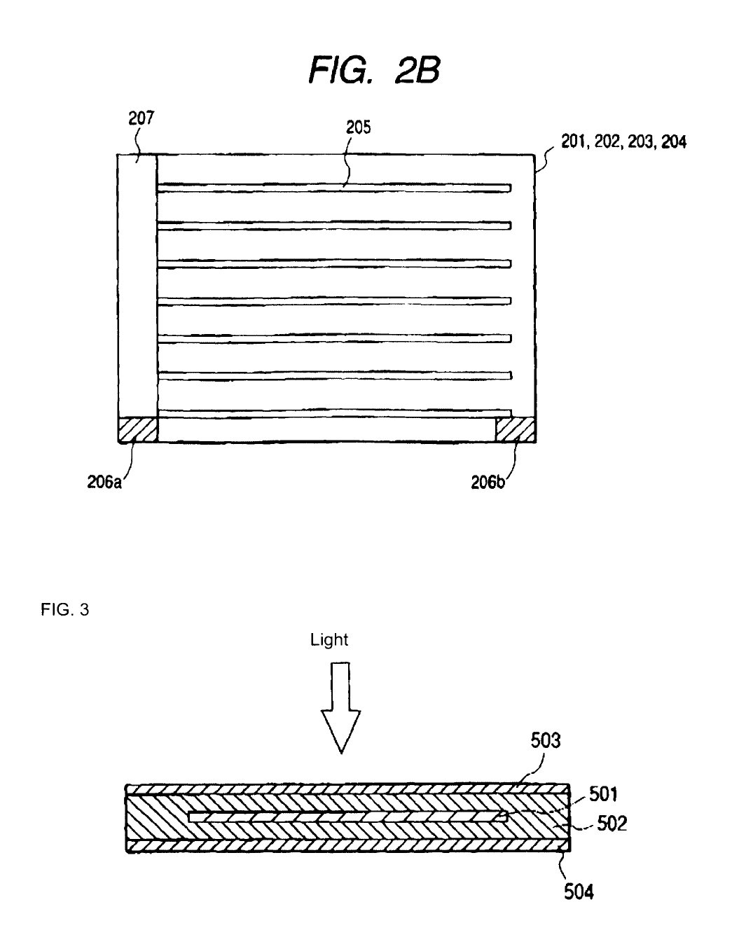

FIG. 2a
201 Conductive substrate
202 Reflective layer
203 Photoactive semiconductor layer
204 Transparent conductive layer
205 Collector electrode
206a Crocodile clip
206b Crocodile clip
207 Conductive, adhesive paste
208 Conductive paste or tin solder

FIG. 2b
201 Conductive substrate
202 Reflective layer
203 Photoactive semiconductor layer
204 Transparent conductive layer
205 Collector electrode
206a Crocodile clip
206b Crocodile clip
207 Conductive, adhesive pastes

FIG. 3
501 Photovoltaic element
502 Fixing means
503 Pane
504 Rear wall

### DETAILED DESCRIPTION OF THE INVENTION

For the purposes of the present invention,

a) at least one polyalkyl (meth)acrylate and
b) at least one compound according to formula (I)

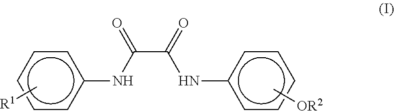

in which the moieties R¹ and R² are independently an alkyl or cycloalkyl moiety having from 1 to 20 carbon atoms,
   are used for the production of solar-cell modules. In this context, these components can be used together in one composition, e.g. as a mixture in a moulding composition, thus using more than one component together in the production of a common element, such as a moulding, of the solar-cell module. However, it is also possible to use each of them separately for the production of different individual elements of a solar-cell module.

The polyalkyl (meth)acrylate can be used alone or else in a mixture of a plurality of different polyalkyl (meth)acrylates. The polyalkyl (meth)acrylate can moreover also take the form of a copolymer.

For the purposes of the present invention, particular preference is given to homo- and copolymers of C₁-C₁₈-alkyl (meth)acrylates, advantageously of C₁-C₁₀-alkyl (meth)acrylates, in particular of C₁-C₄-alkyl (meth)acrylate polymers, and these can, if appropriate, also comprise monomer units which differ therefrom.

The term (meth)acrylate here means not only methacrylate, e.g. methyl methacrylate, ethyl methacrylate, etc., but also acrylate, e.g. methyl acrylate, ethyl acrylate, etc., and also mixtures composed of these two monomers.

It has proved particularly successful to use copolymers which contain from 70% by weight to 99% by weight, in particular from 70% to 90% by weight, of C₁-C₁₀-alkyl (meth)acrylates. Preferred C₁-C₁₀-alkyl methacrylates encompass methyl methacrylate, ethyl methacrylate, propyl methacrylate, isopropyl methacrylate, n-butyl methacrylate, isobutyl methacrylate, tert-butyl methacrylate, pentyl methacrylate, hexyl methacrylate, heptyl methacrylate, octyl methacrylate, isooctyl methacrylate, and ethylhexyl methacrylate, nonyl methacrylate, decyl methacrylate, and also cycloalkyl methacrylates, for example cyclohexyl methacrylate, isobornyl methacrylate or ethylcyclohexyl methacrylate. Preferred C₁-C₁₀-alkylacrylates encompass methyl acrylate, ethyl acrylate, propyl acrylate, isopropyl acrylate, n-butyl acrylate, isobutyl acrylate, tert-butyl acrylate, pentyl acrylate, hexyl acrylate, heptyl acrylate, octyl acrylate, isooctyl acrylate, nonyl acrylate, decyl acrylate, and ethylhexyl acrylate, and also cycloalkyl acrylates, for example cyclohexyl acrylate, isobornyl acrylate or ethylcyclohexyl acrylate.

Very particularly preferred copolymers encompass from 80% by weight to 99% by weight of methyl methacrylate (MMA) units and from 1% by weight to 20% by weight, preferably from 1% by weight to 5% by weight, of C₁-C₁₀-alkyl acrylate units, in particular methyl acrylate units, ethyl acrylate units and/or butyl acrylate units. In this context, it has proved particularly successful to use PLEXIGLAS® 7N polymethyl methacrylate, obtainable from Röhm GmbH.

The polyalkyl (meth)acrylate can be produced by polymerization processes known per se, and particular preference is given here to free-radical polymerization processes, in particular bulk polymerization, solution polymerization, suspension polymerization and emulsion polymerization processes. Initiators particularly suitable for these purposes encompass in particular azo compounds, such as 2,2′-azobis(isobutyronitrile) or 2,2′-azobis(2,4-dimethylvaleronitrile), redox systems, e.g. the combination of tertiary amines with peroxides or sodium disulphite and persulphates of potassium, sodium or ammonium, or preferably peroxides (in which connection cf. for example H. Rauch-Puntigam, Th. Völker, “Acryl- and Methacrylverbindungen” [Acrylic and methacrylic compounds], Springer, Heidelberg, 1967, or Kirk-Othmer, Encyclopedia of Chemical Technology, Vol. 1, pages 386ff, J. Wiley, New York, 1978). Examples of particularly suitable peroxide polymerization initiators are dilauroyl peroxide, tert-butyl peroctoate, tert-butyl perisononanoate, dicyclohexyl peroxodicarbonate, dibenzoyl peroxide and 2,2-bis(tert-butylperoxy)butane. It is also possible and preferred to carry out the polymerization reaction using a mixture of various polymerization initiators of different half-lifetime, examples being dilauroyl peroxide and 2,2-bis(tert-butylperoxy)butane, in order to maintain a constant stream of free radicals during the course of the polymerization reaction, and also at various polymerization temperatures. The amounts used of polymerization initiator are generally from 0.01% by weight to 2% by weight, based on the monomer mixture.

The polymerization reaction can be carried out continuously or else batchwise. After the polymerization reaction, the polymer is obtained by way of conventional steps of isolation and separation, e.g. filtration, coagulation and spray drying.

The chain lengths of the polymers or copolymers can be adjusted by polymerizing the monomer or monomer mixture in the presence of molecular-weight regulators, a particular example being the mercaptans known for this purpose, e.g. n-butyl mercaptan, n-dodecyl mercaptan, 2-mercaptoethanol or 2-ethylhexyl thioglycolate, pentaerythritol tetrathioglycolate; the amounts used of the molecular-weight regulators generally being from 0.05% by weight to 5% by weight, preferably from 0.1 to 2% by weight and particularly preferably from 0.2% by weight to 1% by weight, based on the monomer or monomer mixture (cf., for example, H. Rauch-Puntigam, Th. Völker, “Acryl- and Methacrylverbindungen” [Acrylic and methacrylic compounds], Springer, Heidelberg, 1967; Houben-Weyl, Methoden der organischen Chemie [Methods of organic chemistry], Vol. XIV/1, page 66, Georg Thieme, Heidelberg, 1961, or Kirk-Othmer, Encyclopedia of Chemical Technology, Vol. 1, pages 296ff, J. Wiley, New York, 1978). n-Dodecyl mercaptan is particularly preferably used as molecular-weight regulator.

For the purposes of the present invention, at least one compound according to formula (I)

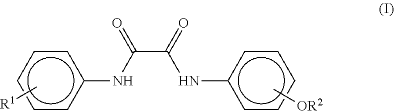

in which the moieties R¹ and R² are independently an alkyl or cycloalkyl moiety having from 1 to 20 carbon atoms, particularly preferably having from 1 to 8 carbon atoms, is moreover used for the production of the solar-cell modules. The aliphatic moieties are preferably linear or branched and can have substituents, examples being halogen atoms.

Among the preferred alkyl groups are the methyl, ethyl, propyl, isopropyl, 1-butyl, 2-butyl, 2-methylpropyl, tert-butyl, pentyl, 2-methylbutyl, 1,1-dimethylpropyl, hexyl, heptyl, octyl, 1,1,3,3-tetramethylbutyl, nonyl, 1-decyl, 2-decyl, undecyl, dodecyl, pentadecyl and eicosyl group.

Among the preferred cycloalkyl groups are the cyclopropyl, cyclobutyl, cyclopentyl, cyclohexyl, cycloheptyl and cyclooctyl group, which optionally have branched or unbranched alkyl groups as substituents.

Preference is given to the use of the compound of the formula (II)

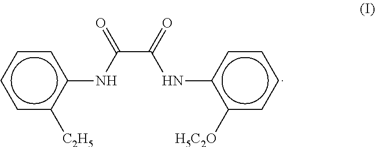

This compound is available commercially from Clariant as ®Sanduvor VSU and from Ciba Geigy as ®Tinuvin 312.

For the purposes of the present invention, it can sometimes be advantageous to add auxiliaries well known to the person skilled in the art. Preference is given to external lubricants, antioxidants, flame retardants, further UV stabilizers, flow aids, metal additives for shielding from electromagnetic radiation, antistatic agents, mould-release agents, dyes, pigments, adhesion promoters, weathering stabilizers, plasticizers, fillers and the like.

For the purposes of one particularly preferred embodiment of the present invention, at least one sterically hindered amine is used, giving a further improvement in weathering resistance. A further reduction can be achieved in yellowing or degradation of the materials when they are exposed to outdoor conditions for long periods.

Particularly preferred sterically hindered amines include dimethyl succinate-1-(2-hydroxyethyl)-4-hydroxy-2,2,6,6-tetramethylpiperazine polycondensate, poly[{6-(1,1,3,3-tetramethylbutyl)amino-1,3,5-triazine-2,4-diyl}{(2,2,6,6-tetramethyl-4-piperidyl)imino}hexamethylene{(2,2,6,6-tetramethyl-4-piperidyl)imino}], N,N′-bis(3-aminopropyl)ethylenediamine-2,4-bis[N-butyl-N-(1,2,2,6,6-pentamethyl-4-piperidyl)amino]-6-chloro-1,3,5-triazine condensate, bis(2,2,6,6-tetramethyl-4-piperidyl)sebacate and bis(1,2,2,6,6-pentamethyl-4-piperidyl) 2-(3,5-di-tert-4-hydroxybenzyl)-2-n-butylmalonate.

The use of silane adhesion promoters or of organic titanium compounds has moreover proved particularly successful, giving a further improvement in adhesion on inorganic materials.

Suitable silane adhesion promoters include vinyltrichlorosilane, vinyltris(β-methoxyethoxy)silane, vinyltriethoxysilane, vinyltrimethoxysilane, γ-methacryloxypropyltrimethoxysilane, β-(3,4-epoxycyclohexyl)ethyltrimethoxysilane, γ-glycidoxypropylmethyldiethoxysilane, N-β-(aminoethyl)-γ-aminopropyltrimethoxysilane, N-β-(aminoethyl)-γ-aminopropylmethyldimethoxysilane, γ-aminopropyltriethoxysilane, N-phenyl-γ-aminopropyltrimethoxysilane, γ-mercaptopropyltrimethoxysilane, and γ-chloropropyltrimethoxysilane.

The relative proportions of the polyalkyl (meth)acrylate and of the compound according to formula (I) can in principle be freely selected.

They are advantageously present together within a moulding composition. Particularly preferred moulding compositions encompass, in each case based on their total weight,

a) from 90% by weight to 99.999% by weight of polyalkyl (meth)acrylate and
b) from 0.001% by weight to 0.03% by weight of compound according to formula (I). The processes known from the literature can be used to incorporate the compounds in such a way that they are present together in a moulding composition, examples being mixing with the polymer prior to further processing at a relatively high temperature, addition to the melt of the polymer or addition to suspended or dissolved polymer during its processing. They can also, if appropriate, be added to the starting materials for the production of the polymer, and they do not lose their absorption capability even in the presence of other conventional light stabilizers and heat stabilizers, oxidants and reducing agents and the like.

The softening point of a moulding composition which is particularly preferred for the purposes of the present invention is not lower than 80° C. (Vicat softening point VST (ISO 306-B50)). It is therefore particularly suitable as fixing means for solar-cell modules, since it does not exhibit any onset of creep even when the module is exposed to high temperatures during use.

Other particularly advantageous moulding compositions are those having comparatively high total light permeability and thus, particularly when the moulding composition is used as fixing means in solar-cell modules, mitigate any reduction in the power level of the solar cell that could be caused by optical loss in the fixing means. Total permeability to light is preferably at least 90% over the wavelength range from 400 nm to less than 500 nm. Total permeability to light is preferably at least 80% over the wavelength range from 500 nm to less than 1000 nm (measured with the aid of a Lambda 19 spectrophotometer from Perkin Elmer).

Still further moulding compositions that are advantageous are those whose dissipation resistance is from 1 to 500 kΩ×cm². This optimizes avoidance of any reduction in the power level from the solar cell caused by short circuits.

Moulding compositions comprising the constituents mentioned are particularly suitable as fastening means for solar-cell modules. They are moreover preferably used for the production of what are known as light concentrators. These are components which concentrate light in a highly efficient manner on an area of minimum size, thus achieving high irradiance. There is no need here to generate an image of the light source.

Particularly advantageous light concentrators for the purposes of the present invention are converging lenses, which collect incident light and focus it in the focal plane. In particular here, light incident parallel to the optical axis is focused at the focal point.

Converging lenses can be biconvex (both sides being convex), planoconvex (1 side planar, 1 side convex) or concave-convex (1 side concave, 1 side convex, the convex side preferably having greater curvature than the concave side). Converging lenses particularly preferred according to the invention encompass at least one convex region, and planoconvex structures have proved very particularly advantageous here.

For the purposes of one particularly preferred embodiment of the present invention, the light concentrators have the structure of a Fresnel lens. This is an optical lens which generally provides a reduction in weight and in volume because of the construction principle used, and this is particularly effective in the case of large lenses with short focal length.

The reduction in volume for a Fresnel lens is achieved through division into annular regions. The thickness is reduced in each of the said regions, and the lens therefore comprises a series of annular zones. Since light is refracted only at the surface of the lens, the angle of refraction depends not on the thickness but only on the angle between the two surfaces of a lens. The lens therefore retains its focal length, although the zoned structure impairs image quality. One first particularly preferred embodiment of the present invention uses rotationally symmetrical lenses using a Fresnel structure with respect to the optical axis. They focus light in a single direction onto a single point.

For the purposes of another particularly preferred embodiment of the present invention, linear lenses with Fresnel structure are used, and focus light within a single plane.

The structure of the solar-cell module can in other respects be a structure known per se. It preferably encompasses at least one photovoltaic element, advantageously inserted and laminated between a pane and a rear wall, where the pane and the rear wall have advantageously and respectively been secured by a fixing means on the photovoltaic element. The solar-cell module here, and in particular the pane, the rear wall and/or the fixing means, advantageously encompasses the components used according to the invention, i.e. the polyalkyl (meth)acrylate and the compound according to formula (I).

For the purposes of another very particularly preferred embodiment of the present invention, the solar-cell module encompasses
a) at least one photovoltaic element,
b) at least one light concentrator, which comprises at least one polyalkyl (meth)acrylate, and
c) at least one transparent pane, which comprises at least one compound according to formula (I).

One particularly advantageous structure of a solar-cell module is described below, with occasional reference to FIGS. 1 to 2B.

The solar-cell module according to the invention preferably encompasses a photovoltaic element 101, a pane 103, covering the frontal side of the photovoltaic element 101, a first fixing means 102 between the photovoltaic element 101 and the pane 103, a rear wall 105, covering the reverse side 104 of the photovoltaic element 101, and a second fixing means 104 between the photovoltaic element 101 and the rear wall 105.

The photovoltaic element preferably encompasses a photoactive semiconductor layer on a conductive substrate as a first electrode for conversion of light, and a transparent conductive layer as a second electrode, formed thereon.

The conductive substrate preferably encompasses in this context stainless steel, giving a further improvement in the adhesion of the fixing means to the substrate.

On the light-sensitive side of the photovoltaic element, there is preferably a collector electrode comprising copper and/or silver as constituent, and a polyalkyl (meth)acrylate which preferably comprises at least one compound according to formula (I) is preferably brought into contact with the collector electrode.

The light-sensitive surface of the photovoltaic element is advantageously covered with a polyalkyl (meth)acrylate which preferably comprises at least one compound according to formula (I) and it is preferable that a thin fluoride polymer film is then arranged as outermost layer thereon.

The first fixing means 102 is intended to protect the photovoltaic element 101 from external effects, by covering any unevenness of the light-sensitive surface of the element 101. It also serves to bond the pane 103 to the element 101. It is therefore intended to have high weathering resistance, high adhesion and high heat resistance, in addition to high transparency. It is moreover intended to exhibit low water absorption and to liberate no acid. In order to meet these requirements, it is preferable to use, as first fixing means, a polyalkyl (meth)acrylate which preferably comprises at least one compound according to formula (I).

In order to minimize the reduction in the amount of light reaching the photovoltaic element 101, it is preferable that the permeability of the first fixing means 102 to light in the visible wavelength range from 400 nm to 800 nm is at least 80%, and particularly preferably at least 90% in the wavelength range from 400 nm to less than 500 nm (measured with the aid of a Lambda 19 spectrophotometer from Perkin Elmer). It also advantageously has a refractive index of from 1.1 to 2.0, advantageously from 1.1 to 1.6, in order to maximize the amount of light incident from air (measured to ISO 489).

The second fixing means 104 is used in order to protect the photovoltaic element 101 from external effects, by covering any unevenness on the reverse side of the element 101. It also serves to bond the rear wall 105 to the element 101. The second fixing means, like the first fixing means, is therefore intended to have high weathering resistance, high adhesion and high heat resistance. It is therefore preferable that a polyalkyl (meth)acrylate which preferably comprises at least one compound according to formula (I) is also used as second fixing means. It is preferable that the material used for the first fixing means is the same as that used for the second fixing means. However, since the transparency is optional, it is possible, if necessary, to add a filler, e.g. an organic oxide, to the second fixing means, in order to achieve a further improvement in weathering resistance and mechanical properties, or to add a pigment in order to colour the fixing means.

The photovoltaic element 101 used preferably comprises known elements, in particular monocrystalline silicon cells, multicrystalline silicon cells, amorphous silicon and microcrystalline silicon, these also being used in thin-layer silicon cells. Copper-indium-selenide compounds and semiconductor compounds are moreover particularly suitable.

FIGS. 2a and 2b show a block diagram of a preferred photovoltaic element. FIG. 2a is a cross-sectional diagrammatic view of a photovoltaic element, whereas FIG. 2b is a diagrammatic plan view of a photovoltaic element. The numeral 201 in these figures indicates a conductive substrate, 202 indicates a reflective layer on the reverse side, 203 indicates a photoactive semiconductor layer, 204 indicates a transparent, conductive layer, 205 indicates a collector electrode, 206a and 206b indicate crocodile clips, and 207 and 208 indicate conductive, adhesive pastes or conductive pastes.

The conductive substrate 201 serves not merely as substrate of the photovoltaic element but also as second electrode. The material of the conductive substrate 201 preferably encompasses silicon, tantalum, molybdenum, tungsten, stainless steel, aluminium, copper, titanium, a carbon foil, a lead-plated steel sheet, a resin film and/or a ceramic material, with a conductive layer thereon.

On the conductive substrate 201, there is preferably a metal layer provided, or a metal oxide layer, or both, as reflective layer 202 on the reverse side. The metal layer preferably encompasses Ti, Cr, Mo, B, Al, Ag and/or Ni, whereas the metal oxide layer preferably comprises ZnO, TiO₂ and SnO₂. The metal layer and the metal oxide layer are advantageously formed by gas-phase deposition, by heating, or by electron beam or by sputtering.

The photoactive semiconductor layer 203 serves to carry out the photoelectric conversion process. In this context, preferred materials are multicrystalline silicon with pn transition, pin junction types composed of amorphous silicon, pin junction types composed of microcrystalline silicon and semiconductor compounds, in particular CuInSe₂, CuInS₂, GaAs, CdS/Cu₂S, CdS/CdTe, CdS/InP and CdTe/Cu₂Te. Particular preference is given here to the use of pin junction types composed of amorphous silicon.

The preferred method of production of a photoactive semiconductor layer uses forming of molten silicon to give a foil, or uses heat treatment of amorphous silicon in the case of polycrystalline silicon, or uses plasma gas-phase deposition with use of a silane gas as starting material in the case of amorphous silicon and of microcrystalline silicon, or uses ion plating, ion beam deposition, vacuum evaporation, sputtering or electroplating in the case of a semiconductor compound.

The transparent conductive layer 204 serves as upper electrode of the solar cell. It preferably encompasses In₂O₃, SnO₂, In₂O₃—SnO₂(ITO), ZnO, TiO₂, Cd₂SnO₄ or a crystalline semiconductor layer which has been doped with a high concentration of impurities. It can be formed by resistance-heating vapour deposition, sputtering, spraying, gas-phase deposition, or diffusion of impurities.

Another aspect of the photovoltaic element on which the transparent conductive layer 204 has been formed is that some degree of short circuit can arise between the conductive substrate and the transparent, conductive layer, due to the unevenness of the surface of the conductive substrate 201 and/or to non-uniformity at the juncture of formation of the photoactive semiconductor layer. The result here is a large current loss, proportional to the output voltage. This means that the leakage resistance (shunt resistance) is low. It is therefore desirable to eliminate the short circuits and to subject the photovoltaic element to a treatment for the removal of defects, after formation of the transparent conductive layer. U.S. Pat. No. 4,729,970 describes this type of treatment in detail. The said treatment adjusts the shunt resistance of the photovoltaic element to from 1 to 500 kΩ×cm², preferably from 10 to 500 kΩ×cm².

The collector electrode (grid) can be formed on the transparent conductive layer 204. It preferably takes the form of a grid, of a cone, or of a line or the like, in order to be an effective electrical collector. Preferred examples of the material forming the collector electrode 205 are Ti, Cr, Mo, W, Al, Ag, Ni, Cu, Sn, or a conductive paste, which is termed silver paste.

The collector electrode 205 is preferably formed by a sputtering using a masking pattern, by resistance heating, by gas-phase deposition, by a process encompassing the steps of forming a metal film by gas deposition over the entire layer and using etching to remove superfluous portions of the film, by a process which uses photochemical gas-phase deposition to form a grid-electrode pattern, by a process encompassing the steps of producing a marked pattern of the grid electrode in negative form and plating the patterned surface, by a process in which a conductive paste is applied by printing, or by a process in which metal wires are soldered onto a printed conductive paste. The conductive paste used is preferably a binder polymer comprising silver, gold, copper, nickel, carbon or the like dispersed in the form of a fine powder. The binder polymer preferably includes polyester resins, ethoxy resins, acrylic resins, alkyd resins, polyvinyl acetate resins, rubbers, urethane resins and/or phenolic resins.

Finally, crocodile clips 206 are preferably secured on the conductive substrate 201 or on the collector electrode 205, in order to tap the electromotive force. In a preferred method of fixing the crocodile clips 206 on the conductive substrate, a metal body, e.g. a copper tag, is secured by spot welding or soldering on the conductive substrate, while the crocodile clips are preferably secured on the collector electrode by using a conductive paste or tin solder 207 and 208 to make an electrical connection between a metal body and the collector electrode.

The photovoltaic elements can be connected in series or in parallel, in accordance with the desired voltage or current level. The voltage or current level can also be controlled by introducing the photovoltaic elements into an insulating substrate.

The pane 103 in FIG. 1 is intended to have maximum weathering resistance, maximum dirt repellency and maximum mechanical strength, since it is the outermost layer of the solar-cell module. It is moreover intended to ensure that the solar-cell module is reliable in long-term outdoor use. Panes suitable for use for the purposes of the present invention include (reinforced) glass foils and fluoride polymer films. The glass foil preferably used is a glass foil with high permeability to light. Suitable fluoride polymer foils encompass in particular ethylene tetrafluoride-ethylene copolymer (ETFE), polyvinyl fluoride resin (PVF), polyvinylidene fluoride resin (PVDF), tetrafluoroethylene resin (TFE), ethylene tetrafluoride-propylene hexafluoride copolymer (FEP) and chlorotrifluoroethylene (CTFE). The polyvinylidene fluoride resin is particularly suitable with regard to weathering resistance, while ethylene tetrafluoride ethylene copolymer is particularly advantageous with regard to combination of weathering resistance and mechanical strength. In order to improve adhesion between the fluoride polymer foil and the fixing means, it is desirable to subject the foil to a corona treatment or a plasma treatment. It is also preferable to use stretched foils, in order to achieve a further improvement in mechanical strength.

For the purposes of one particularly preferred embodiment of the present invention, the pane encompasses at least one polyalkyl (meth)acrylate which preferably further comprises at least one compound according to formula (I).

The pane is moreover preferably a light concentrator, which concentrates light with high efficiency on the photovoltaic element, i.e. achieves high irradiance. Particular preference is given to converging lenses which collect parallel incident light and focus it within the focal plane. In particular here, light incident parallel to the optical axis is focused at the focal point.

The converging lenses can be biconvex, planoconvex or concave-convex. However, particular preference is given to planoconvex structures. The pane moreover preferably has the structure of a Fresnel lens.

The rear wall 105 serves for electrical insulation between the photovoltaic element 101 and the environment, and for improving weathering resistance, and acts as reinforcing material. It is preferably composed of a material which provides reliably adequate electrical insulation properties, and which has excellent long-term stability and which can withstand thermal expansion and thermal contraction, and which is flexible. Materials particularly suitable for these purposes include nylon foils, polyethylene terephthalate (PET) foils and polyvinyl fluoride foils. If moisture resistance is demanded, it is preferable to use aluminium-laminated polyvinyl fluoride foils, aluminium-coated PET foils, or silicon-oxide-coated PET foils. The fire resistance of the module can moreover be improved by using, as rear wall, a foil-laminated, electroplated iron foil or a foil composed of stainless steel.

For the purposes of one particularly preferred embodiment of the present invention, the rear wall encompasses at least one polyalkyl (meth)acrylate which preferably further comprises at least one compound according to formula (I).

There can be a supportive plate secured on the external surface of the rear wall, in order to achieve a further improvement in the mechanical strength of the solar-cell module or in order to inhibit buckling and deflection of the rear wall caused by temperature changes. Particularly preferred rear walls are stainless-steel sheets, plastics sheets, and FRP (fibre-reinforced plastics) sheets. There can also be a construction material secured on the rear pane.

This type of solar-cell module can be produced in a manner known per se. However, a particularly advantageous procedure is described below.

A preferred procedure for covering the photovoltaic element with the fixing means uses heat to melt the fixing means and extrudes this through a slot in order to form a foil, which is then secured thermally on the element. The fixing-means foil is preferably introduced between the element and the pane and between the element and the rear wall, and then consolidated.

The thermal consolidation process can be carried out using known processes, e.g. vacuum lamination and roller lamination.

The operating temperature of the solar-cell module according to the invention is preferably up to 80° C. or higher, and it is in particular high temperatures here which permit effective utilization of the heat-resistance effect of the materials according to the invention.

1-8. (canceled)

9. A solar-cell module, comprising a moulding composition, wherein said moulding composition, comprises
a) at least one polyalkyl (meth)acrylate and
b) at least one compound according to formula (I) 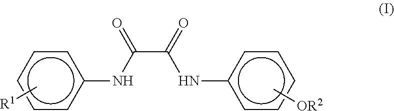
in which the moieties R¹ and R² are independently an alkyl or cycloalkyl moiety having from 1 to 20 carbon atoms.

10. The solar-cell module according to claim 9, wherein the moulding is a light concentrator.

11. The solar-cell module according to claim 10, wherein the moulding is a converging lens.

12. The solar-cell module according to claim 11, wherein the converging lens encompasses a convex region.

13. The solar-cell module according to claim 12, wherein the converging lens has a planoconvex structure.

14. The solar-cell module according to claim 13, wherein the converging lens is a Fresnel lens.

15. The solar-cell module according to claim 10, comprising a photovoltaic element.

16. A solar-cell module, comprising
a) at least one photovoltaic element
b) at least one converging lens, which comprises at least one polyalkyl (meth)acrylate,
and
c) at least one transparent pane, which comprises at least one compound according to formula (I) 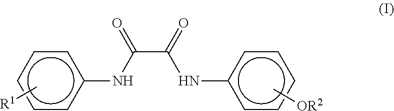
in which the moieties R¹ and R² are independently an alkyl or cycloalkyl moiety having from 1 to 20 carbon atoms.

17. The solar-cell module according to claim 9, wherein the moulding composition comprises at least one C₁-C₁₈-alkyl (meth)acrylate homopolymer or C₁-C₁₈-alkyl (meth)acrylate copolymer.

18. The solar-cell module according to claim 9, wherein the moulding composition comprises at least one copolymer which encompasses from 80% by weight to 99% by weight of methyl methacrylate units and from 1% by weight to 20% by weight of C₁-C₁₀-alkyl acrylate units.

19. The solar-cell module according to claim 18, wherein the copolymer encompasses methyl acrylate units and/or ethyl acrylate units.

20. The solar-cell module according to claim 9, wherein in the compound according to formula (I) the moieties R¹ and R² are independently an alkyl or cycloalkyl moiety having from 1 to 8 carbon atoms.

21. The solar-cell module according to claim 9, wherein in the compound according to formula (I) the moieties R¹ and R² are a methyl, ethyl, propyl, isopropyl, 1-butyl, 2-butyl, 2-methylpropyl, tert-butyl, pentyl, 2-methylbutyl, 1,1-dimethylpropyl, hexyl, heptyl, octyl, 1,1,3,3-tetramethylbutyl, nonyl, 1-decyl, 2-decyl, undecyl, dodecyl, pentadecyl or eicosyl group.

22. The solar-cell module according to claim 9, wherein in the compound according to formula (I) the moieties R¹ and R² are a cyclopropyl, cyclobutyl, cyclopentyl, cyclohexyl, cycloheptyl or cyclooctyl group, optionally having branched or unbranched alkyl groups as substituents.

23. The solar-cell module according to claim 9 comprising a compound according to formula (II) [chemical structure]
